(19) United States
(12) Patent Application Publication
(10) Pub. No.: US 2009/0040823 A1
(43) Pub. Date: Feb. 12, 2009

(54) FLASH MEMORY

(76) Inventors: Shin-Bin Huang, Hsinchu County (TW); Ching-Nan Hsiao, Kaohsiung County (TW); Chung-Lin Huang, Tao-Yuan City (TW)

Correspondence Address: NORTH AMERICA INTELLECTUAL PROPERTY CORPORATION, P.O. BOX 506, MERRIFIELD, VA, 22116, US

(21) Appl. No.: 11/946,872

(22) Filed: Nov. 29, 2007

(30) Foreign Application Priority Data
Aug. 8, 2007 (TW) 096129298

(51) Int. Cl. G11C 16/04

(52) U.S. Cl. 365/185.05

(57) ABSTRACT

A flash memory is provided. A sawtooth gate conductor line, which interconnects the select gates of the select gate transistors arranged on the same column is provided. The sawtooth gate conductor line, which is disposed on both distal ends of a memory cell string, increases the integration of the flash memory. The sawtooth gate conductor line results in select gate transistors having different select gate lengths and produces at least one depletion-mode select transistor at one side of the memory cell string. The select gate transistor of the depletion-mode is always turned on.

### BACKGROUND OF THE INVENTION

1. Field of the Invention

The present invention relates to a memory, and more particularly to the layout and the structure of a NAND flash memory.

2. Description of the Prior Art

Recently, as demands for the portable electronic devices are increasing, the market for the flash memory and the electrically erasable programmable read-only memory (EEPROM) is also expanding as well. The aforesaid portable electronic device includes the storage memory for the digital camera, the cell phones, the video game apparatuses, PDAs, telephone answering machines, and the programmable ICs, etc. A flash memory belongs to a non-volatile memory, and has an important characteristic of being able to store data in the memory even though the power is turned off. By changing the threshold voltage of the transistor, the gate can be turned on and off, and the data can be stored in the transistor. Generally speaking, the flash memory can be divided into two types of configurations, namely, a NOR flash memory and a NAND flash memory. The drains of the memory cells of a NOR flash memory are connected in parallel for a faster reading speed, which is suitable for code flash memory mainly used for executing program codes. The drains and sources of two neighboring memory cells of a NAND flash memory are serially connected for integrating more memory cells per unit area, which is suitable for a data flash memory mainly used for data storage. Both of the NOR flash memory and the NAND flash memory have a MOS-like memory cell structure, so as to provide advantages of smaller size, higher operation speed, and higher density.

As the electronic device becomes smaller, integration of the flash memory needs to be increased. Therefore, it is an object of the present invention to provide a new layout and structure for the flash memory to increase the integration of the flash memory. The layout design according to the present invention can make the size of the flash memory smaller.

### SUMMARY OF THE INVENTION

According to the flash memory disclosed in the present invention, the flash memory comprises a substrate; a first active area positioned in the substrate, wherein the first active area comprises a first memory cell string, a first select gate transistor, and a second select gate transistor arranged in sequence in the same row, wherein the first select gate transistor comprises a first gate channel length, and the second select gate transistor comprises a second gate channel length; and a second active area positioned in the substrate, wherein the second active area comprises a second memory cell string, a third select gate transistor, and a fourth select gate transistor arranged in sequence in the same row, wherein the third select gate transistor comprises a third gate channel length, and the fourth select gate transistor comprises a fourth gate channel length, wherein the first select gate transistor and the third select gate transistor are arranged in the same column and are electrically connected with each other, and the second select gate transistor and the fourth select gate transistor are arranged in the same column and are electrically connected with each other, and wherein the first gate channel length is substantially equal to the third gate channel length, and the second gate channel length is substantially equal to the fourth gate channel length, and the first gate channel length is not equal to the second gate channel length.

The layout of the flash memory of the present invention includes a sawtooth (having blunt tips) structure, which can increase the integration of the elements, and the effectiveness of the Optical Proximity Correction (OPC) can be improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic layout of a NAND type flash memory according to the present invention.

FIG. 2a shows a sectional view as viewed along the active area 54 in FIG. 1 according to the NAND type flash memory of the present invention.

FIG. 2b shows a sectional view as viewed along the active area 68 in FIG. 1 according to the NAND type flash memory of the present invention.

FIG. 2c shows a sectional view as viewed along the active area 80 in FIG. 1 according to the NAND type flash memory of the present invention.

FIG. 2d shows a sectional view as viewed along the active area 92 in FIG. 1 according to the NAND type flash memory of the present invention.

FIG. 3 to FIG. 8 show the operating method of the NAND type flash memory according to the present invention.

### DETAILED DESCRIPTION

The structure of the NAND type flash memory according to the present invention features a structure of a plurality of dual gate transistors (dual SG), which is meant to have two ends of the memory cell strings connected to two select gate transistors in series, respectively. In addition, each storage transistor positioned in the memory cell strings is a two-bit storage transistor.

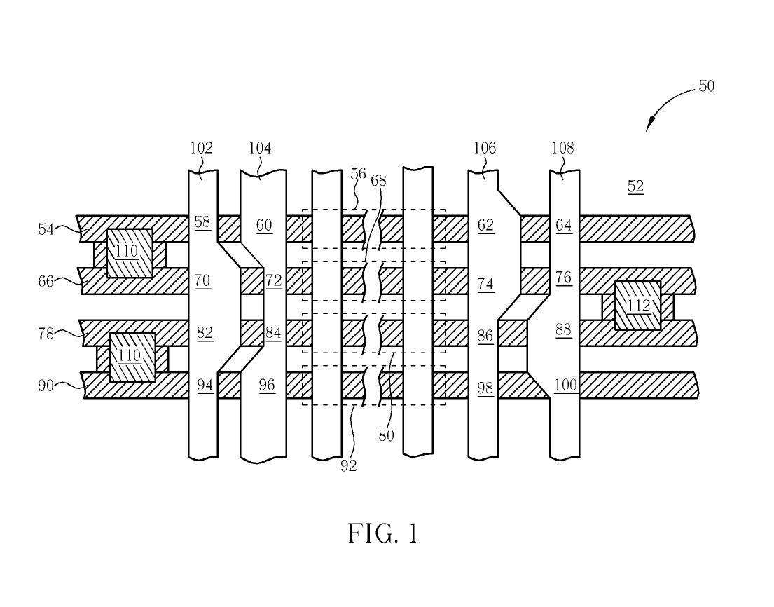

FIG. 1 shows a schematic layout of a NAND type flash memory according to the present invention. As shown in FIG. 1, a NAND type flash memory 50 comprises: a substrate 52, a plurality of active areas 54, 66, 78, 90 positioned in the substrate 52, in which the active area 54 comprises a plurality of select gate transistors 58, 60, a memory cell string 56, and a plurality of select gate transistors 62, 64 arranged in sequence, in the same row, and in which the select gate transistors 58, 60 are positioned at a side of the memory cell string 56, and the select gate transistors 62, 64 are positioned at the other side of the memory cell string 56. Furthermore, each of the select gate transistors 58, 64 has a gate channel length L₁, respectively, and each of the select gate transistors 60, 62 has a gate channel length L₂, respectively.

The active area 66 comprises a plurality of select gate transistors 70, 72, a memory cell string 68, and a plurality of select gate transistors 74, 76 arranged in sequence, in the same row, and in which the select gate transistors 70, 72 are positioned at a side of the memory cell string 66, and the select gate transistors 74, 76 are positioned at the other side of the memory cell string 66.

Furthermore, each of the select gate transistors 72, 76 has the gate channel length L₁ respectively, and each of the select gate transistors 70, 74 has the gate channel length L₂ respectively.

The active area 78 comprises a plurality of select gate transistors 82, 84, a memory cell string 80, and a plurality of select gate transistors 86, 88 arranged in sequence, in the same row. Furthermore, each of the select gate transistors 84, 86 has the gate channel length L₁, respectively, and each of the select gate transistors 82, 88 has the gate channel length L₂, respectively.

The active area 90 comprises a plurality of select gate transistors 94, 96, a memory cell string 92, and a plurality of select gate transistors 98, 100 arranged in sequence, in the same row. Furthermore, each of the select gate transistors 84, 86 has the gate channel length L₁, respectively, and each of the select gate transistors 82, 88 has the gate channel length L₂, respectively.

The gate channel length L₁ mentioned above is shorter than the gate channel length L₂ according to the present invention. According to a preferred embodiment of the present invention, the gate channel length L₁ is shorter than half of the gate channel length L₂. In addition, during operation, the gate channel length L₁ is always in a depletion mode, which means that the select gate transistors 58, 64, 72, 76, 84, 86, 94, 98 wherein each having the gate channel length L₁, respectively, are always on during operation.

Additionally, the select gate transistors 58, 70, 82, 94 which are arranged in a same column are coupled to each other in sequence electrically through a gate conductor 102 in the NAND type flash memory 50. Because the select gate transistors 58, 70, 82, 94 possess only two gate channel lengths L₁, L₂, the gate conductor 102 forms a sawtooth structure in an orderly repetitive manner by using the two gate channel lengths L₁, L₂, which is one feature of the present invention.

Similarly, the select gate transistors 60, 72, 84, 96 which are arranged in a same column are coupled to each other in sequence electrically through a gate conductor 104. The select gate transistors 62, 74, 86, 98 which are arranged in a same column are coupled to each other in sequence electrically through a gate conductor 106. The select gate transistors 64, 76, 88, 100 which are arranged in a same column are coupled to each other in sequence electrically through a gate conductor 108. The gate conductors 104, 106, 108 form a sawtooth structure in an orderly repetitive manner as well.

In addition, a plurality of bit-line contact pads 110, 112 are positioned at a side of the gate conductors 102, 108, respectively, for transmitting the bit-line signals.

The sawtooth structure can increase the integration of the elements. For example, the sum of the gate channel lengths of the select gate transistor 58 and the select gate transistor 60 can be shrunken to around 0.4 μm. Therefore, the space that the gate conductors occupied according to the present invention is smaller than the space that the gate conductors occupied according to the conventional technology.

It is another feature of the present invention that the adjacent select gate transistors which are arranged in the same column have an identical gate channel length. For example, the select gate transistors 70, 82 comprise the gate channel length L₁, respectively and the select gate transistors 72, 84 comprise the gate channel length L₂, respectively. As a result, not only can the integration of the elements be increased, the effectiveness of the Optical Proximity Correction (OPC) can also be improved as well.

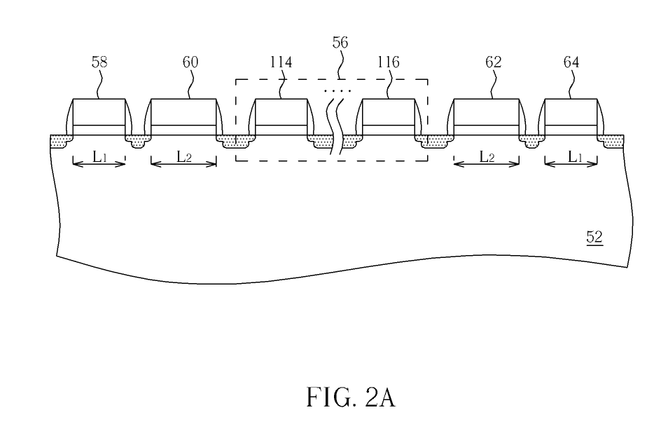

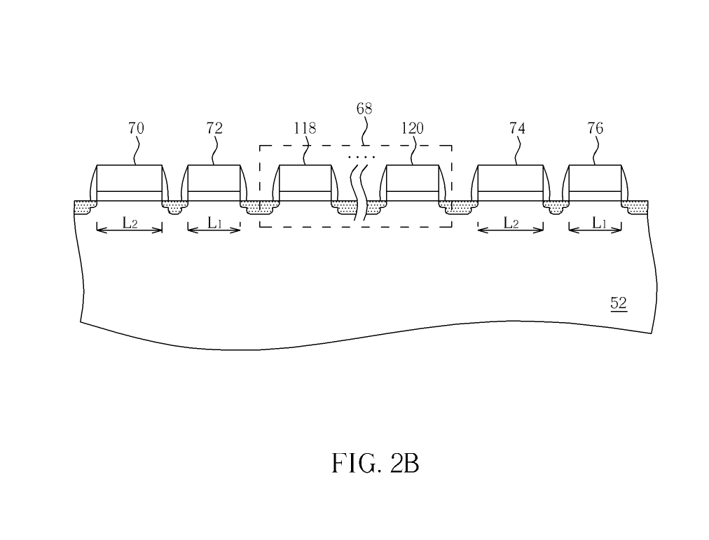

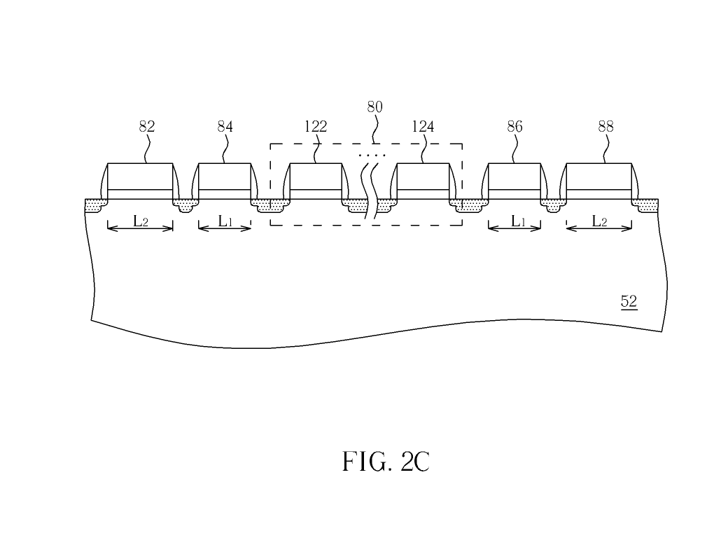

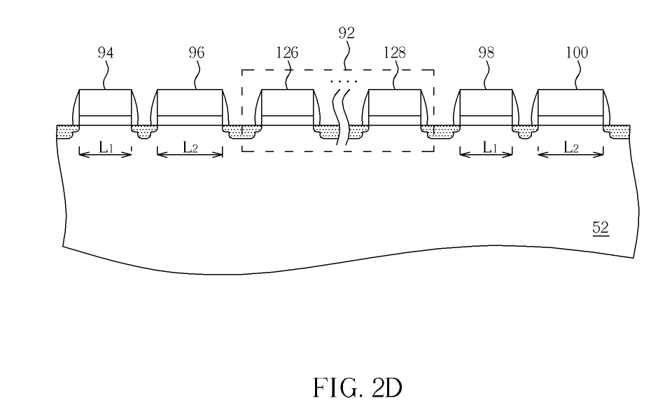

FIG. 2a shows a sectional view as viewed along the active area 54 shown in FIG. 1 according to the NAND type flash memory of the present invention. As shown in FIG. 2a, the flash memory 50 comprises a substrate 52, a memory cell string 56 positioned on the substrate 52, a select gate transistor 60 comprising a gate channel length L₂, a select gate transistor 58 comprising a gate channel length L₁, a select gate transistor 62 comprising a gate channel length L₂, and a select gate transistor 64 comprising a gate channel length L₁.

The select gate transistor 60 is directly connected to a side of the memory string 56 in series, and the select gate transistor 58 is directly connected to the select gate transistor 60 in series; the select gate transistor 62 is directly connected to another side of the memory string 56 in series, and the select gate transistor 64 is directly connected to the select gate transistor 62 in series.

In addition, the aforementioned memory cell string 56 comprises a plurality of two-bit storage transistors, such as the two-bit storage transistors 114, 116, in which the number of the two-bit storage transistors included in the memory cell string 56 can be 16 or 32, and all of the two-bit storage transistors may be PMOS transistors. The gate channel length L₁ is shorter than the gate channel length L₂ according to the present invention; according to a preferred embodiment of the present invention, the gate channel length L₁ is shorter than half of the gate channel length L₂. In addition, during operation, the gate channel length L₁ is always in a depletion mode, which means that the select gate transistors 58, 64 having the gate channel length L₁ are always on during operation.

FIG. 2b shows a sectional view as viewed along the active area 66 shown in FIG. 1 according to the NAND type flash memory of the present invention. As shown in FIG. 2b, the flash memory 50 comprises a substrate 52, a memory cell string 68 positioned on the substrate 52, a select gate transistor 72 comprising a gate channel length L₁, a select gate transistor 70 comprising a gate channel length L₂, a select gate transistor 74 comprising a gate channel length L₂, and a select gate transistor 76 comprising a gate channel length L₁, in which the select gate transistor 72 is directly connected to a side of the memory string 68 in series, and the select gate transistor 70 is directly connected to the select gate transistor 72 in series; the select gate transistor 74 is directly connected to another side of the memory cell string 68 in series, and the select gate transistor 76 is directly connected to the select gate transistor 74 in series. In addition, the memory cell string 68 comprises a plurality of two-bit storage transistors, such as the two-bit storage transistors 118, 120, in which the number of the two-bit storage transistors included in the memory cell string 68 can be 16 or 32, and all of the two-bit storage transistors may be PMOS transistors.

The gate channel length L₁ is shorter than the gate channel length L₂ according to the present invention; according to a preferred embodiment of the present invention, the gate channel length L₁ is shorter than half of the gate channel length L₂. In addition, during operation, the gate channel length L₁ is always in a depletion mode, which means that the select gate transistors 72,76 having the gate channel length L₁ are always turned on during operation.

FIG. 2c shows a sectional view as viewed along the active area 78 shown in FIG. 1 according to the NAND type flash memory of the present invention. As shown in FIG. 2c, the flash memory 50 comprises a substrate 52, a memory cell string 80 positioned on the substrate 52, a select gate transistor 84 comprising a gate channel length L₁, a select gate transistor 82 comprising a gate channel length L₂, a select gate transistor 86 comprising a gate channel length L₁, and a select gate transistor 88 comprising a gate channel length L₂ in which the select gate transistor 84 is directly connected to a side of the memory string 80 in series, and the select gate transistor 82 is directly connected to the select gate transistor 84 in series; the select gate transistor 86 is directly connected to another side of the memory string 80 in series, and the select gate transistor 88 is directly connected to the select gate transistor 86 in series. In addition, the memory cell string 80 comprises a plurality of two-bit storage transistors, such as the two-bit storage transistors 122, 124, in which the number of the two-bit storage transistors included in the memory cell string 80 can be 16 or 32, and all of the two-bit storage transistors may be PMOS transistors. The gate channel length L₁ is shorter than the gate channel length L₂ according to the present invention; according to a preferred embodiment of the present invention, the gate channel length L₁ is shorter than half of the gate channel length L₂. In addition, during operation, the gate channel length L₁ is always in a depletion mode, which means that the select gate transistors 84, 86 having the gate channel length L₁ are always on during operation.

FIG. 2d shows a sectional view as viewed along the active area 90 shown in FIG. 1 according to the NAND type flash memory of the present invention. As shown in FIG. 2d, the flash memory 50 comprises a substrate 52, a memory cell string 92 positioned on the substrate 52, a select gate transistor 96 comprising a gate channel length L₂, a select gate transistor 94 comprising a gate channel length L₁, a select gate transistor 98 comprising a gate channel length L₁, and a select gate transistor 100 comprising a gate channel length L₂, in which the select gate transistor 96 is directly connected to a side of the memory string 92 in series, and the select gate transistor 94 is directly connected to the select gate transistor 96 in series; the select gate transistor 98 is directly connected to another side of the memory string 92 in series, and the select gate transistor 100 is directly connected to the select gate transistor 98 in series. In addition, the memory cell string 92 comprises a plurality of two-bit storage transistors, such as the two-bit storage transistors 126, 128, in which the number of the two-bit storage transistors included in the memory cell string 92 can be 16 or 32, and all of the two-bit storage transistors may be PMOS transistors.

The gate channel length L₁ is shorter than the gate channel length L₂ according to the present invention; according to a preferred embodiment of the present invention, the gate channel length L₁ is shorter than half of the gate channel length L₂. In addition, during operation, the gate channel length L₁ is always in a depletion mode, which means that the select gate transistors 94,96 having the gate channel length L₁ are always on during operation.

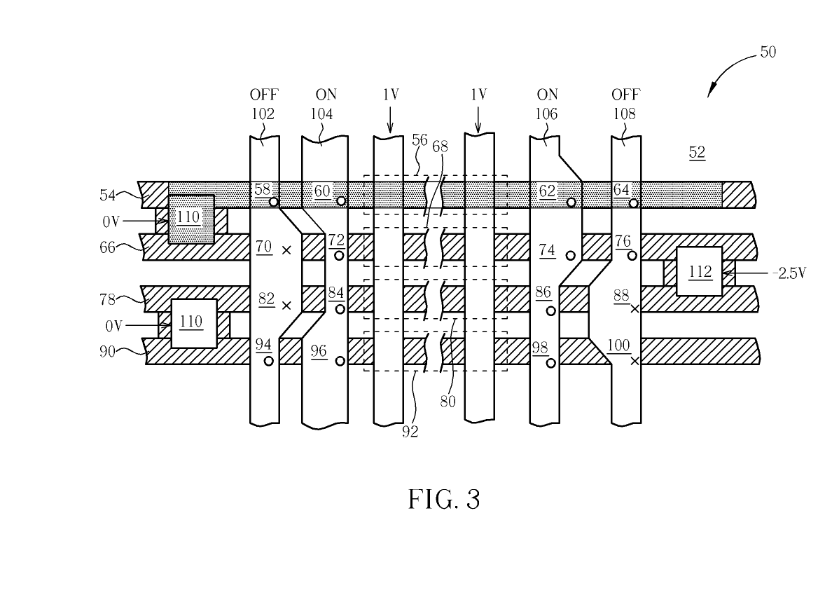

FIG. 3 to FIG. 8 show the operating method of the NAND type flash memory 50 according to the present invention.

FIG. 3 shows the operating method in which the memory cell string 56 is read. As shown in FIG. 3, the gate conductors 102, 108 are turned off, and the gate conductors 104, 106 are turned on; 1 volt is applied to the memory cell strings 56, 68, 80, 92; 0 volt is applied to the bit-line contact pad 110; −2.5 volts is applied to the bit-line contact pad 112; and 0 volt is applied to the substrate 52 (not shown).

Notably, the select gate transistors 58, 64, 72, 76, 84, 86, 94, 98 are always turned on, because they are in the depletion mode. Therefore, the turning on and off of the gate conductors 102, 104, 106, 108 are to only control the on and off of the select gate transistors 60, 62, 70, 74, 82, 88, 96, 100. In this way, the one bit of each the two-bit storage transistors positioned in the memory cell string 56 can be read.

In FIG. 3, the select gate transistor having the symbol “∘” depicted on it is to mean that the select gate transistor is turned on, and the select gate transistor having the symbol [symbol] depicted on it is to mean that the select gate transistor is turned off.

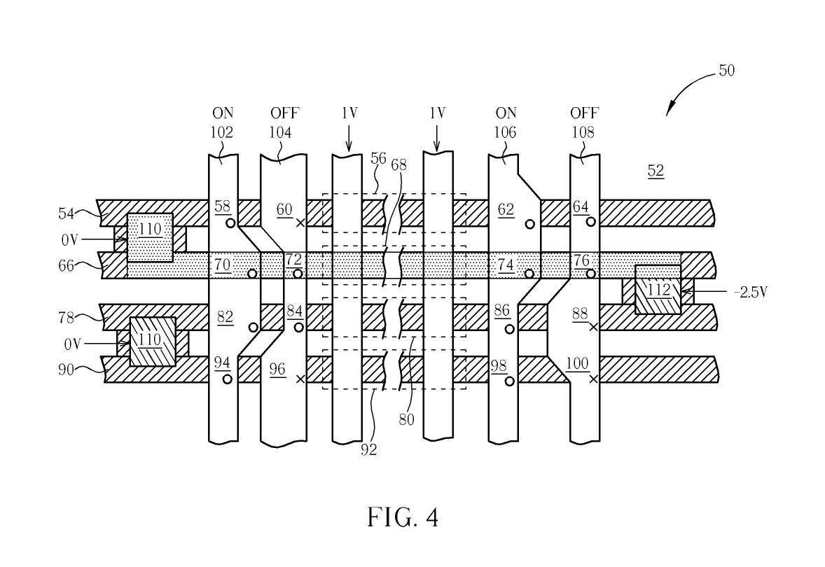

In FIG. 4 to FIG. 8, the select gate transistor having the symbol “∘” depicted on it is to mean that the select gate transistor is turned on, and the select gate transistor having the symbol [symbol] depicted on it is to mean that the select gate transistor is turned off.

FIG. 4 shows the operating method in which the memory cell string 68 is read. As shown in FIG. 4, the gate conductors 104, 108 are turned off and the gate conductors 102, 106 are turned on; 1 volt is applied to the memory cell strings 56, 68, 80, 92; 0 volt is applied to the bit-line contact pad 110; −2.5 volts is applied to the bit-line contact pad 112; and 0 volt is applied to the substrate 52 (not shown). In this way, the one bit of each two-bit storage transistor positioned in the memory cell string 68 can be read.

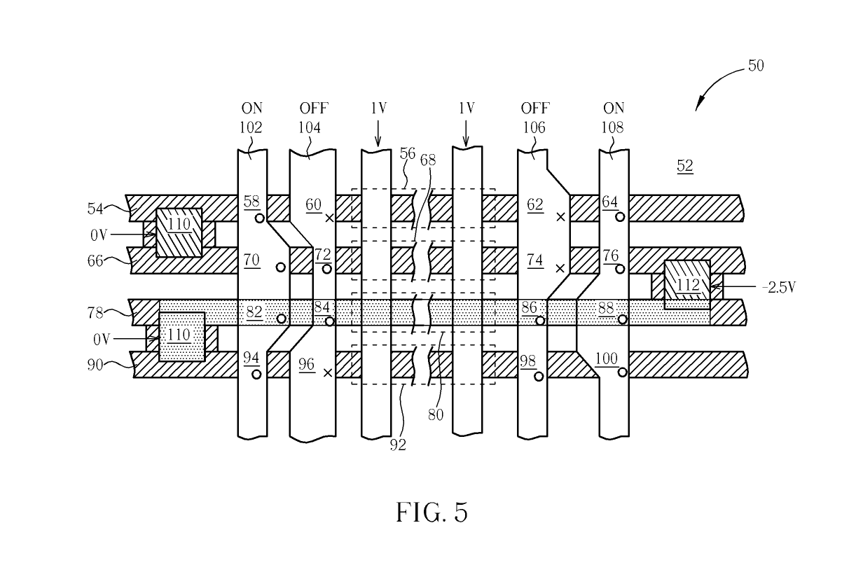

FIG. 5 shows the operating method in which the memory cell string 80 is read. As shown in FIG. 5, the gate conductors 104, 106 are turned off, and the gate conductors 102, 108 are turned on; 1 volt is applied to the memory cell strings 56, 68, 80, 92; 0 volt is applied to the bit-line contact pad 110; −2.5 volts is applied to the bit-line contact pad 112; and 0 volt is applied to the substrate 52 (not shown). In this way, the one bit of each two-bit storage transistor positioned in the memory cell string 80 can be read.

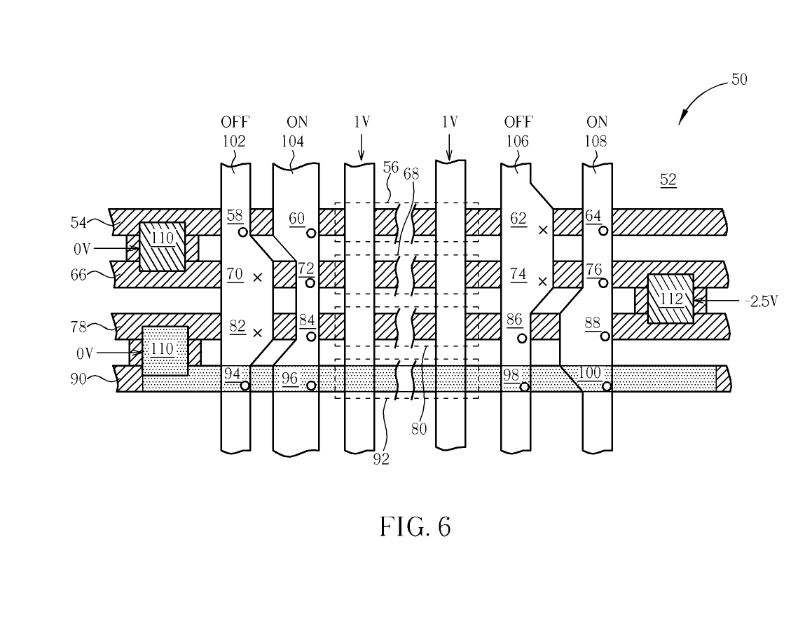

FIG. 6 shows the operating method in which the memory cell string 92 is read. As shown in FIG. 6, the gate conductors 102, 106 are turned off and the gate conductors 104, 108 are turned on; 1 volt is applied to the memory cell strings 56, 68, 80, 92; 0 volt is applied to the bit-line contact pad 110; −2.5 volts is applied to the bit-line contact pad 112; and 0 volt is applied to the substrate 52 (not shown). In this way, the one bit of each two-bit storage transistor positioned in the memory cell string 92 can be read.

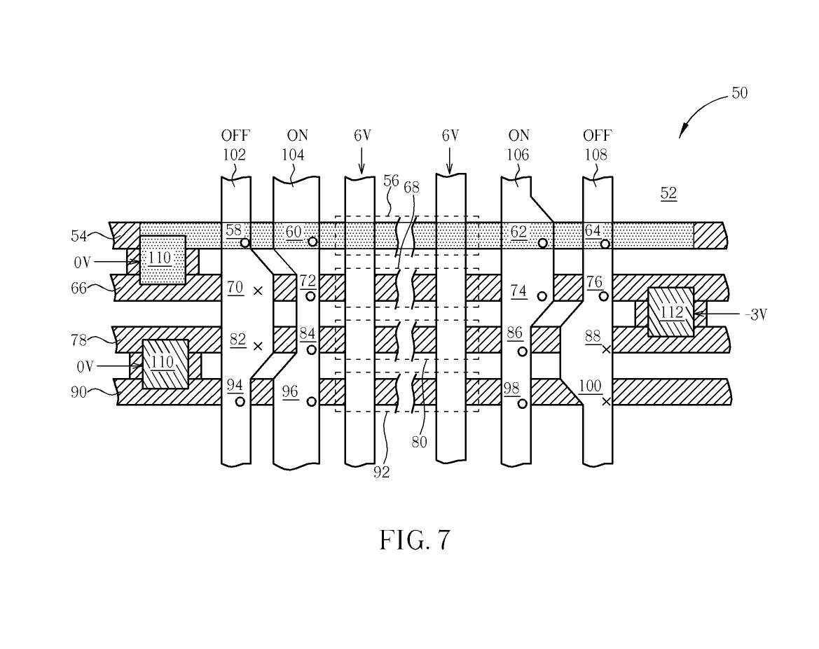

FIG. 7 shows the operating method in which the memory cell strings 56 are programmed. As shown in FIG. 7, the gate conductors 102, 108 are turned off, and the gate conductors 104, 106 are turned on; 6 volt is applied to the memory cell strings 56, 68, 80, 92; 0 volt is applied to the bit-line contact pad 110; −3 volts is applied to the bit-line contact pad 112; and 0 volt is applied to the substrate 52 (not shown). In this way, data can be programmed into the memory cell strings 56.

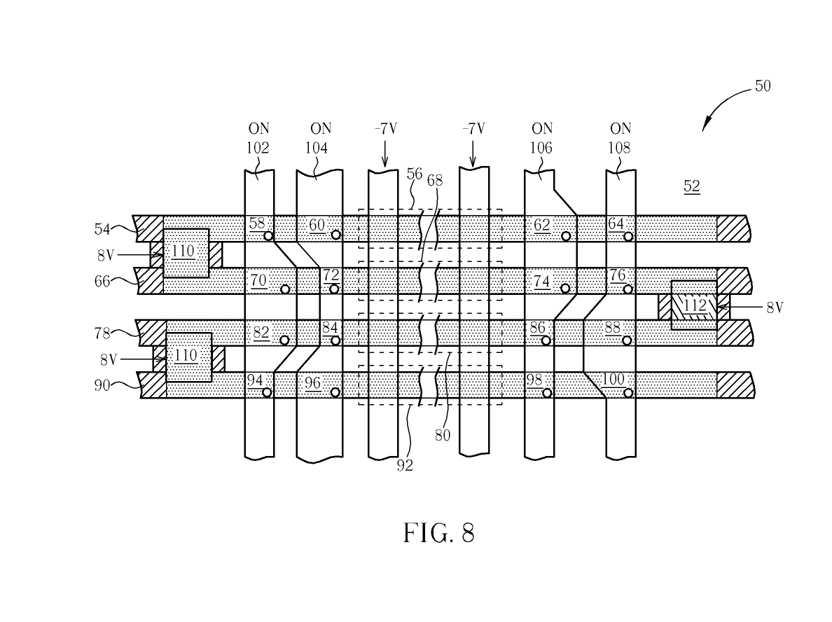

FIG. 8 shows the operating method in which the memory cell strings 56, 68, 80, 92 are block erased. As shown in FIG. 8, the gate conductors 102, 104, 106, 108 are turned on; −7 volts is applied to the memory cell strings 56, 68, 80, 92; 8 volts is applied to the bit-line contact pad 112; 8 volts is applied to the bit-line contact pad 110; and 8 volts (not shown) is applied to the substrate 52. In this way, data stored in the memory cell strings 56, 68, 80, 92 can be block erased.

Those skilled in the art will readily observe that numerous modifications and alterations of the device and method may be made while retaining the teachings of the invention.

What is claimed is:

1. A flash memory, comprising:
a substrate;
a memory cell string positioned on the substrate;
a first select gate transistor positioned at a side of the memory cell string and having a first gate channel length; and
a second select gate transistor positioned at a side of the first select gate transistor away from the memory cell string and having a second gate channel length, wherein the second select gate transistor is directly connected to the first select gate transistor in series, and the first gate channel length is shorter than the second gate channel length, and thereby the first select gate transistor is always on during operation.

2. The flash memory of claim 1, wherein the first gate channel length is shorter than half of the second gate channel length.

3. The flash memory of claim 1, wherein the memory cell string comprises a plurality of two-bit storage transistors.

4. The flash memory of claim 2, wherein the memory cell string comprises a plurality of two-bit storage transistors.

5. The flash memory of claim 4 further comprising a bit line contact pad positioned at a side of the second select gate transistor.

6. A flash memory, comprising:
a substrate;
a first active area positioned in the substrate, wherein the first active area comprises a first memory cell string, a first select gate transistor, and a second select gate transistor arranged in sequence in the same row; the first select gate transistor comprises a first gate channel length; and the second select gate transistor comprises a second gate channel length; and
a second active area positioned in the substrate, wherein the second active area comprises a second memory cell string, a third select gate transistor, and a fourth select gate transistor arranged in sequence in the same row; the third select gate transistor comprises a third gate channel length; and the fourth select gate transistor comprises a fourth gate channel length;
the first select gate transistor and the third select gate transistor are arranged in the same column; and the second select gate transistor and the fourth select gate transistor are arranged in the same column; the first gate channel length is substantially equal to the third gate channel length, and the second gate channel length is substantially equal to the fourth gate channel length.

7. The flash memory of claim 6, wherein the first gate channel length is shorter than the second gate channel length.

8. The flash memory of claim 7, wherein the first gate channel length is shorter than half of the second gate channel length.

9. The flash memory of claim 7, wherein the first memory cell string comprises a plurality of first two-bit storage transistors.

10. The flash memory of claim 8, wherein the first memory cell string comprises a plurality of first two-bit storage transistors.

11. The flash memory of claim 10, wherein the second memory cell string comprises a plurality of second two-bit storage transistors.

12. The flash memory of claim 11, wherein the first select gate transistor is adjacent to the third select gate transistor.

13. The flash memory of claim 12, wherein the second select gate transistor is adjacent to the fourth select gate transistor.

14. A flash memory, comprising:
a substrate;
a memory cell string positioned on the substrate;
a first select gate transistor positioned at a side of the memory cell string and having a first gate channel, wherein the first gate channel comprises a first gate channel length; and
a second select gate transistor positioned at a side of the first select gate transistor away from the memory cell string and comprising a second gate channel, wherein the second select gate transistor is directly connected to the first select gate transistor in series, and the second gate channel length is shorter than the first gate channel length, and thereby the second select gate transistor is always on during operation.

15. The flash memory of claim 14, wherein the second gate channel length is shorter than half of the first gate channel length.

16. The flash memory of claim 15, wherein the memory cell string comprises a plurality of two-bit storage transistors.

17. The flash memory of claim 12 further comprising a bit line contact pad positioned at a side of the second select gate transistor.
